(19) United States
(12) Patent Application Publication
(10) Pub. No.: US 2025/0076362 A1
(43) Pub. Date: Mar. 6, 2025

(54) SYSTEMS AND METHODS FOR DETECTING DEFECTS IN CABLES

(71) Applicant: Florida State University Research Foundation, Inc., Tallahassee, FL (US)

(72) Inventor: Virginia Phifer, Tallahassee, FL (US)

(21) Appl. No.: 18/821,564

(22) Filed: Aug. 30, 2024

Related U.S. Application Data
(60) Provisional application No. 63/580,147, filed on Sep. 1, 2023.

(51) Int. Cl. G01R 31/08; G01R 33/00; G01R 33/07

(52) U.S. Cl. CPC G01R 31/083; G01R 33/072; G01R 33/0094

(57) ABSTRACT

Systems and methods for detecting anomalies in current distribution in cables are provided An array of Hall sensors can be disposed in proximity to a cable to be examined for defects. The array of Hall sensors can scan along a length of the cable to measure changes in the radial magnetic field produced by current redistribution. If an anomaly in the current distribution is detected in the cable, this can be indicative of a defect.

### CROSS-REFERENCE TO RELATED APPLICATION

This application claims the benefit of U.S. Provisional Application Ser. No. 63/580,147, filed Sep. 1, 2023, the disclosure of which is hereby incorporated by reference in its entirety, including all figures, tables, and drawings.

### GOVERNMENT SUPPORT

This invention was made with government support under DE-EE0007872 awarded by the Department of Energy. The government has certain rights in the invention.

### BACKGROUND

The manufacturing process of rare-earth barium copper oxides (REBCOs), a class of high temperature superconductors, can result in defects that locally constrict the flow of current. These defects can be exacerbated and new defects can be created due to the stresses introduced from conductor handling, such as winding into cables and magnets, in conjunction with the magnetic stresses experienced during operation.

### BRIEF SUMMARY

Embodiments of the subject invention provide novel and advantageous systems and methods for detecting anomalies in current distribution in cables (e.g., conductor on round core (CORC) cables). An array of Hall sensors can be disposed in proximity to a cable to be examined for defects. The array of Hall sensors can scan along a length of the cable (e.g., the entire cable or any portion thereof). During scanning, the Hall sensors can measure changes in the radial magnetic field produced by current redistribution. If an anomaly in the current distribution is detected in the cable, this can be indicative of a defect. The array of Hall sensors can be disposed on and/or in operable communication with a motor (e.g., a stepper motor) to control movement of the array. The motor can be connected one or more gears and/or lead screws to move the motor. The array can be positioned at any location along the axis of the cable to be examined. The array can be disposed, for example, directly underneath the cable during scanning.

In an embodiment, a method for detecting a defect in a cable can comprise: a) disposing an array of Hall sensors in proximity to the cable; b) moving at least one of the cable and the array of Hall sensors such that a position of the array of Hall sensors with respect to the cable changes along an axis of the cable; c) measuring, by the array of Hall sensors during step b), changes in a radial magnetic field produced by current redistribution in the cable; and d) if any anomalies are measured in the radial magnetic field during step c), determining that a defect is present in the cable at a location corresponding to each anomaly, respectively. The cable can be, for example, a CORC cable. Each Hall sensor in the array of Hall sensors can be a z-axis Hall sensor. The array of Hall sensors can be disposed, for example, directly below the cable. The array of Hall sensors can be moved by a motor (e.g., a stepper motor) in operable communication with the array of Hall sensors. The motor can be connected to at least one gear (e.g., a worm gear) and/or at least one lead screw. The array of Hall sensors can be in operable communication with a processor and a machine-readable medium that analyze the changes in the radial magnetic field produced by current redistribution in the cable for anomalies. The array of Hall sensors can be in operable communication with a display that displays the changes in the radial magnetic field produced by current redistribution in the cable.

In another embodiment, a system for detecting a defect in a cable can comprise: a cable holder configured to hold the cable; and an array of Hall sensors disposed in proximity to the cable holder. The system can be configured to move at least one of the cable and the array of Hall sensors such that a position of the array of Hall sensors with respect to the cable changes along an axis of the cable. The array of Hall sensors can be configured to measure changes in a radial magnetic field produced by current redistribution in the cable (e.g., as the array moves with respect to the cable along the cable axis). The array of Hall sensors can be configured such that, if any anomalies are measured in the radial magnetic field, it is determined that a defect is present in the cable at a location corresponding to each anomaly, respectively. The cable can be, for example, a CORC cable. Each Hall sensor in the array of Hall sensors can be a z-axis Hall sensor. The array of Hall sensors can be disposed, for example, directly below the cable holder. The system can further comprise a motor (e.g., a stepper motor) in operable communication with the array of Hall sensors, and the motor can be configured to move the array of Hall sensors. The system can further comprise at least one gear (e.g., a worm gear) connected to the motor and/or at least one lead screw connected to the motor. The system can further comprise a processor and a machine-readable medium in operable communication with the array of Hall sensors, that analyze the changes in the radial magnetic field produced by current redistribution in the cable for anomalies. The system can further comprise a display in operable communication with the array of Hall sensors, that displays the changes in the radial magnetic field produced by current redistribution in the cable.

### BRIEF DESCRIPTION OF DRAWINGS

FIG. 1 shows an image of an array of Hall sensors disposed below a conductor on round core (CORC) cable, according to an embodiment of the subject invention.

FIG. 2 shows an image of a stepper motor connected to a worm gear and a lead screw, according to an embodiment of the subject invention.

FIG. 3 shows an image of an array of Hall sensors disposed below a CORC cable, according to an embodiment of the subject invention. Though a range for location along the cable length is given, this is for exemplary purposes only and should not be construed as limiting. The array can be disposed at any position along a cable of any length.

### DETAILED DESCRIPTION

Embodiments of the subject invention provide novel and advantageous systems and methods for detecting anomalies in current distribution in cables (e.g., conductor on round core (CORC) cables). An array of Hall sensors can be disposed in proximity to a cable to be examined for defects. The array of Hall sensors can scan along a length of the cable (e.g., the entire cable or any portion thereof). During scanning, the Hall sensors can measure changes in the radial magnetic field produced by current redistribution. If an anomaly in the current distribution is detected in the cable, this can be indicative of a defect. The array of Hall sensors can be disposed on and/or in operable communication with a motor (e.g., a stepper motor) to control movement of the array. The motor can be connected one or more gears and/or lead screws to move the motor. The array can be positioned at any location along the axis of the cable to be examined. The array can be disposed, for example, directly underneath the cable during scanning.

Reel-to-reel systems can scan long lengths of conductor for uniformity and detect defects. Systems and methods of embodiments of the subject invention can scan along cables (e.g., CORC cables) to detect defects, such as those introduced during winding, which can lead to changes in current distribution within the cable. Uneven current distributions can lead to imbalances in the magnetic field, quenches, or sudden transition out of the superconducting state resulting in a large release of energy, which may be dissipated as heat. Information on defect location advantageously allows for more knowledgeable instrumentation and protection of superconducting magnets.

CORC cables and wires include multiple layers of rare-earth barium copper oxide (REBCO tapes), helically wound around a copper former with adjacent layers wound in opposing directions (i.e., a layer is wound clockwise and then an adjacent layer is wound counterclockwise, etc.). This configuration causes the axial components of the magnetic field to cancel out. The presence of a defect causes current redistribution between conductors, producing imbalance in the magnetic field components, which can be detected by z-axis Hall sensors in embodiments of the subject invention.

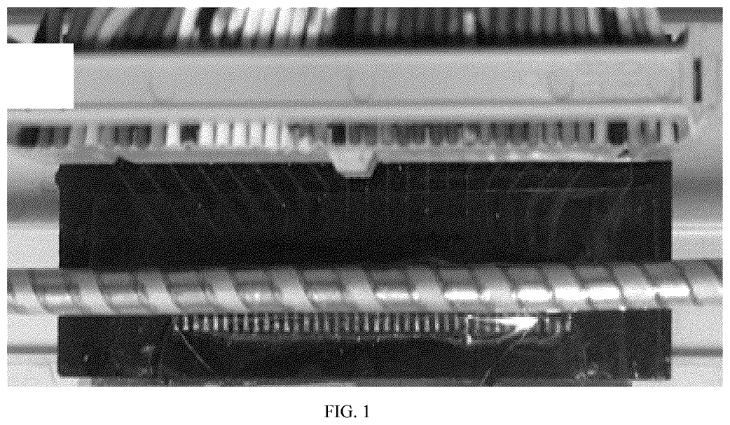

FIG. 1 shows an image of an array of Hall sensors disposed below a CORC cable, according to an embodiment of the subject invention. Referring to FIG. 1, the system can include an array of Hall sensors located in proximity (e.g., directly underneath) the cable. The array of Hall sensors can scan along the length of the cable and measure changes in the radial magnetic field produced by current redistribution. The array of Hall sensors may be in operable communication with a processor, a machine-readable medium, and/or a display for analyzing and/or displaying the results of the scan in order to help determine the location of any defects in the cable.

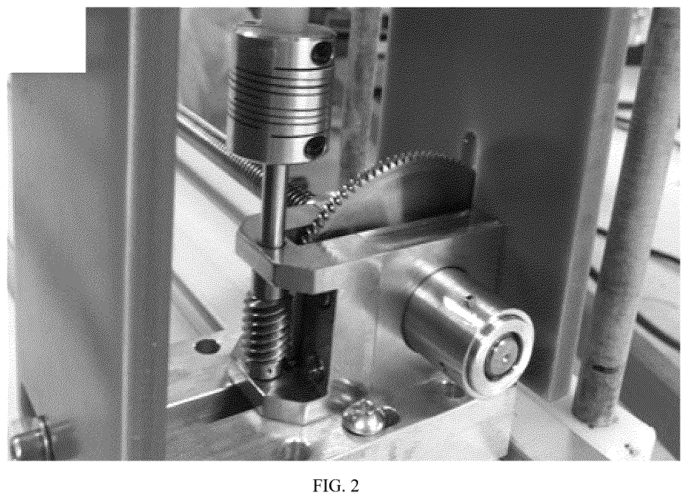

The position of the array of Hall sensors can be controlled by a motor (e.g., a stepper motor), which may be connected to one or more gears and/or one or more lead screws. FIG. 2 shows an image of a stepper motor connected to a worm gear and a lead screw, which can be used to control the position of the array of Hall sensors.

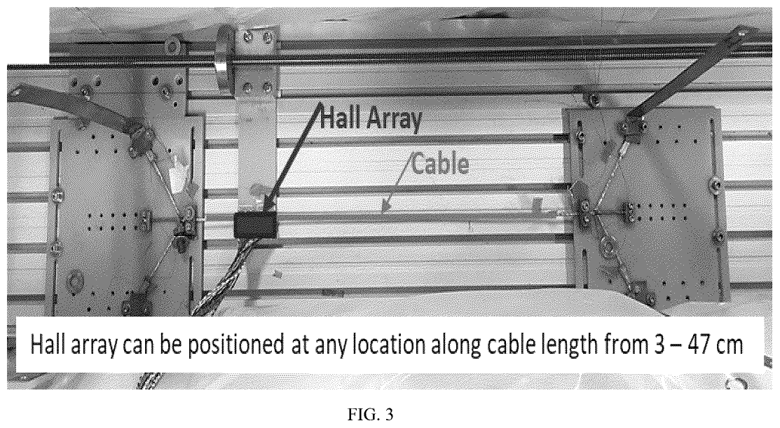

FIG. 3 shows an image of an array of Hall sensors disposed below a CORC cable, according to an embodiment of the subject invention. Referring to FIG. 3, the array of Hall sensors can be positioned at any location along the cable axis.

The methods and processes described herein can be embodied as code and/or data. The software code and data described herein can be stored on one or more machine-readable media (e.g., computer-readable media), which may include any device or medium that can store code and/or data for use by a computer system. When a computer system and/or processor reads and executes the code and/or data stored on a computer-readable medium, the computer system and/or processor performs the methods and processes embodied as data structures and code stored within the computer-readable storage medium.

It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), and magnetic and optical storage devices (hard drives, magnetic tape, CDs, DVDs); network devices; or other media now known or later developed that are capable of storing computer-readable information/data. Computer-readable media should not be construed or interpreted to include any propagating signals. A computer-readable medium of embodiments of the subject invention can be, for example, a compact disc (CD), digital video disc (DVD), flash memory device, volatile memory, or a hard disk drive (HDD), such as an external HDD or the HDD of a computing device, though embodiments are not limited thereto. A computing device can be, for example, a laptop computer, desktop computer, server, cell phone, or tablet, though embodiments are not limited thereto.

When ranges are used herein, combinations and subcombinations of ranges (e.g., subranges within the disclosed range), as well as specific embodiments therein, are intended to be explicitly included. When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. A method for detecting a defect in a cable, the method comprising:
a) disposing an array of Hall sensors in proximity to the cable;
b) moving at least one of the cable and the array of Hall sensors such that a position of the array of Hall sensors with respect to the cable changes along an axis of the cable,
c) measuring, by the array of Hall sensors during step b), changes in a radial magnetic field produced by current redistribution in the cable; and
d) if any anomalies are measured in the radial magnetic field during step c), determining that a defect is present in the cable at a location corresponding to each anomaly, respectively.

2. The method according to claim 1, wherein the cable is a conductor on round core (CORC) cable.

3. The method according to claim 1, wherein each Hall sensor in the array of Hall sensors is a z-axis Hall sensor.

4. The method according to claim 1, wherein the array of Hall sensors is disposed directly below the cable.

5. The method according to claim 1, wherein the array of Hall sensors is moved by a motor in operable communication with the array of Hall sensors.

6. The method according to claim 5, wherein the motor is a stepper motor.

7. The method according to claim 5, wherein the motor is connected to at least one gear and at least one lead screw.

8. The method according to claim 5, wherein the motor is connected to a worm gear and a lead screw.

9. The method according to claim 1, wherein the array of Hall sensors is in operable communication with a processor and a machine-readable medium that analyze the changes in the radial magnetic field produced by current redistribution in the cable for anomalies.

10. The method according to claim 1, wherein the array of Hall sensors is in operable communication with a display that displays the changes in the radial magnetic field produced by current redistribution in the cable.

11. A system for detecting a defect in a cable, the system comprising:
a cable holder configured to hold the cable; and
an array of Hall sensors disposed in proximity to the cable holder,
wherein the system is configured to move at least one of the cable and the array of Hall sensors such that a position of the array of Hall sensors with respect to the cable changes along an axis of the cable,
wherein the array of Hall sensors is configured to measure changes in a radial magnetic field produced by current redistribution in the cable, and
wherein the array of Hall sensors is configured such that, if any anomalies are measured in the radial magnetic field, it is determined that a defect is present in the cable at a location corresponding to each anomaly, respectively.

12. The system according to claim 11, wherein the cable is a conductor on round core (CORC) cable.

13. The system according to claim 11, wherein each Hall sensor in the array of Hall sensors is a z-axis Hall sensor.

14. The system according to claim 11, wherein the array of Hall sensors is disposed directly below the cable holder.

15. The system according to claim 11, further comprising a motor in operable communication with the array of Hall sensors, wherein the motor is configured to move the array of Hall sensors.

16. The system according to claim 15, wherein the motor is a stepper motor.

17. The system according to claim 15, further comprising at least one gear connected to the motor and at least one lead screw connected to the motor.

18. The system according to claim 15, further comprising a worm gear connected to the motor and a lead screw connected to the motor.

19. The system according to claim 11, further comprising a processor and a machine-readable medium in operable communication with the array of Hall sensors, that analyze the changes in the radial magnetic field produced by current redistribution in the cable for anomalies.

20. The system according to claim 11, further comprising a display in operable communication with the array of Hall sensors, that displays the changes in the radial magnetic field produced by current redistribution in the cable.
